(19) United States
(12) Patent Application Publication
(10) Pub. No.: US 2023/0200157 A1
(43) Pub. Date: Jun. 22, 2023

(54) Organic Light Emitting Display Device and Method of Fabricating the Same

(71) Applicant: LG Display Co., Ltd., Seoul (KR)

(72) Inventors: Sun-Wook Ko, Paju-si (KR); Kum-Mi Oh, Paju-si (KR); Deuk-Ho Yeon, Paju-si (KR)

(21) Appl. No.: 17/836,925

(22) Filed: Jun. 9, 2022

(30) Foreign Application Priority Data
Dec. 22, 2021 (KR) 10-2021-0184918

(51) Int. Cl. H01L 27/32; H01L 51/56

(52) U.S. Cl. CPC H01L 27/3276; H01L 51/56; G09G 3/3233; G09G 2300/0426; G09G 2300/0842

(57) ABSTRACT

The present disclosure relates to an organic light emitting display device and a method of fabricating the same. The organic light emitting display device comprises a first substrate including a plurality of sub-pixels; a thin film transistor in each of the plurality of sub-pixels and on the first substrate; an organic light emitting diode in each of the plurality of sub-pixels and on the first substrate; and an aging voltage supply line extending from a lower surface of the first substrate to a portion of the thin film transistor and supplying an aging voltage to the thin film transistor.

### CROSS-REFERENCE TO RELATED APPLICATIONS

The present application claims the benefit of Korean Patent Application No. 10-2021-0184918 filed in the Republic of Korea on Dec. 22, 2021, which is hereby incorporated by reference in its entirety.

### BACKGROUND

### Field of Technology

The present disclosure relates to an organic light emitting display device and a method of fabricating the same, and more particularly, to an organic light emitting display device with easy aging and a method of fabricating the same.

### Discussion of the Related Art

Recently, with the development of multimedia, the importance of a flat panel display device is increasing, and flat panel display devices, such as a liquid crystal display device, a plasma display device, and an organic light emitting display device, are being commercialized. Among these flat panel display devices, the organic light emitting display device is currently widely used because of high response speed, high luminance and good viewing angle.

However, the organic light emitting display device may have following problems.

An organic light emitting element (e.g., an organic light emitting diode (OLED) emitting light and a thin film transistor (TFT) for applying a signal to the OLED are disposed in one sub-pixel of the organic light emitting display device. The TFT is operated as a signal is applied from the outside, and when a current is applied to the OLED through the TFT, light corresponding to the current is emitted from the OLED.

As described above, in the organic light emitting display device, the OLED is controlled by the TFT. When a leakage current occurs in the TFT, the luminance of the display device becomes non-uniform. In addition, even when the OLED is turned off, a current is applied to the OLED so that the OLED emits light. Accordingly, there is a problem in that a bright spot or a bright line is generated on a non-operational screen.

### SUMMARY

The embodiments of the present disclosure are directed to an organic light emitting display device and a method of fabricating the same that substantially obviate one or more of the problems associated with the limitations and disadvantages of the related conventional art.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is an organic light emitting display device comprising a first substrate including a plurality of sub-pixels; a thin film transistor in each of the plurality of sub-pixels and on the first substrate; an organic light emitting diode in each of the plurality of sub-pixels and on the first substrate; and an aging voltage supply line extending from a lower surface of the first substrate to a portion of the thin film transistor and supplying an aging voltage to the thin film transistor.

The thin film transistor may include a semiconductor layer over the first substrate and under a gate insulating layer; a gate electrode on the gate insulating layer and under an interlayer insulating layer; and a source electrode and a drain electrode on the interlayer insulating layer.

The aging voltage supply line may include a first aging voltage supply line in a first contact hole through the first substrate and the gate insulating layer and connected to the gate electrode; and a second aging supply line in a second contact hole through the first substrate, the gate insulating layer and the interlayer insulating layer and connected to the drain electrode.

The first aging voltage supply line may be formed of the same material as the gate electrode.

The second aging voltage supply line may be formed of the same material as the drain electrode.

The organic light emitting display device may further comprise a metal pattern on the gate insulating layer.

The aging voltage supply line may include a first aging voltage supply line in a first contact hole through the first substrate and the gate insulating layer and connected to the gate electrode; a second aging supply line in a second contact hole through the first substrate and the gate insulating layer and connected to the metal pattern; and a third aging supply line in a third contact hole through the interlayer insulating layer and connecting the metal pattern and the drain electrode.

The first aging voltage supply line may be formed of the same material as the gate electrode.

The second aging voltage supply line and the metal pattern may be formed of the same material as the gate electrode.

The third aging voltage supply line may be formed of the same material as the drain electrode.

An end of the aging volage supply line may be exposed at the lower surface of the first substrate.

The organic light emitting display device may further comprise a sealing layer disposed on the lower surface of the first substrate and sealing the end of the aging voltage supply line.

The sealing layer may have a pattern shape corresponding to the end of the aging voltage supply line.

The sealing layer may have a film shape corresponding to an entire of the lower surface of the first substrate.

Another aspect of the present disclosure is a method of fabricating an organic light emitting display device comprising steps of: forming an aging voltage line on a support substrate; disposing a first substrate including a plurality of sub-pixels; forming a thin film transistor and an organic light emitting diode in each of the plurality of sub-pixels and on the first substrate; connecting the aging voltage line to the thin film transistor by an aging voltage supply line; and aging the thin film transistor by applying an aging voltage to the thin film transistor through the aging voltage line and the aging voltage supply line.

An aging pad may be formed at an end of the aging voltage line.

The step of forming the thin film transistor includes: forming a semiconductor layer over the first substrate and under a gate insulating layer; forming a gate electrode on the gate insulating layer and under an interlayer insulating layer; and forming a source electrode and a drain electrode on the interlayer insulating layer.

The step of connecting the aging voltage line to the thin film transistor by the aging voltage supply line includes: forming a first aging voltage supply line in a first contact hole through the first substrate and the gate insulating layer and connected to the gate electrode; and forming a second aging supply line in a second contact hole through the first substrate, the gate insulating layer and the interlayer insulating layer and connected to the drain electrode.

The step of connecting the aging voltage line to the thin film transistor by the aging voltage supply line includes: forming a first aging voltage supply line in a first contact hole through the first substrate and the gate insulating layer and connected to the gate electrode; forming a second aging supply line in a second contact hole through the first substrate and the gate insulating layer and connected to the metal pattern; and forming a third aging supply line in a third contact hole through the interlayer insulating layer and connecting the metal pattern and the drain electrode.

The method of fabricating an organic light emitting display device may further comprise forming a sacrificial layer on the support substrate before the step of disposing the first substrate; and separating the support substrate from the first substrate after the step of aging the thin film transistor.

It is to be understood that both the foregoing general description and the following detailed description are exemplary and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic block diagram of an organic light emitting display device according to the present disclosure.

FIG. 2 is a schematic block diagram of a sub-pixel of an organic light emitting display device according to the present disclosure.

FIG. 3 is a schematic circuit diagram of a sub-pixel of an organic light emitting display device according to the present disclosure.

FIG. 4 is a schematic cross-sectional view of an organic light emitting display device according to a first embodiment of the present disclosure.

FIG. 5 is a schematic plan view illustrating a structure of first and second aging voltage lines.

FIG. 6 is a view illustrating an electrical property of a driving TFT in the organic light emitting display device.

FIGS. 7A to 7I are schematic cross-sectional views illustrating a method of fabricating the organic light emitting display device according to the first embodiment of the present disclosure.

FIG. 8 is a schematic cross-sectional view of an organic light emitting display device according to a second embodiment of the present disclosure.

### DETAILED DESCRIPTION

Advantages and features of the present invention and methods of achieving them will be apparent with reference to the embodiments described below in detail with the accompanying drawings. However, the present invention is not limited to the embodiments disclosed below, but can be realized in a variety of different forms, and only these embodiments allow the disclosure of the present invention to be complete. The present invention is provided to fully inform the scope of the invention to the skilled in the art of the present invention, and the present invention is only defined by the scope of the claims.

The shapes, sizes, proportions, angles, numbers, and the like disclosed in the drawings for explaining the embodiments of the present invention are illustrative, and the present invention is not limited to the illustrated matters. The same reference numerals refer to the same elements throughout the specification. In addition, in describing the present invention, if it is determined that a detailed description of the related known technology unnecessarily obscure the subject matter of the present invention, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

In interpreting the components, even if there is no separate explicit description, it is interpreted as including a margin range.

In the case of a description of the positional relationship, for example, when the positional relationship of two parts is described as ‘on’, ‘over’, ‘under’, ‘next to’, and the like, one or more other parts may be positioned between two parts unless ‘right’, ‘directly’ or ‘adjacent’ is described.

In the case of a description of a temporal relationship, for example, when the temporal relationship is described as ‘after’, ‘following’, ‘after’, ‘before’, and the like, it includes cases that are not continuous unless ‘immediately’ or ‘directly’ is described.

Although the first, second, etc. are used to describe various elements, these elements are not limited by these terms. These terms are only used to distinguish one element from another element. Accordingly, the first element mentioned below may be the second element within the spirit of the present invention.

Each feature of the various embodiments of the present specification may be partially or wholly connected to or combined with each other and may be technically interlocked and driven. Each of the embodiments may be independently realized from each other or may be realized together with a related relationship.

Reference will now be made in detail to some of the examples and preferred embodiments, which are illustrated in the accompanying drawings.

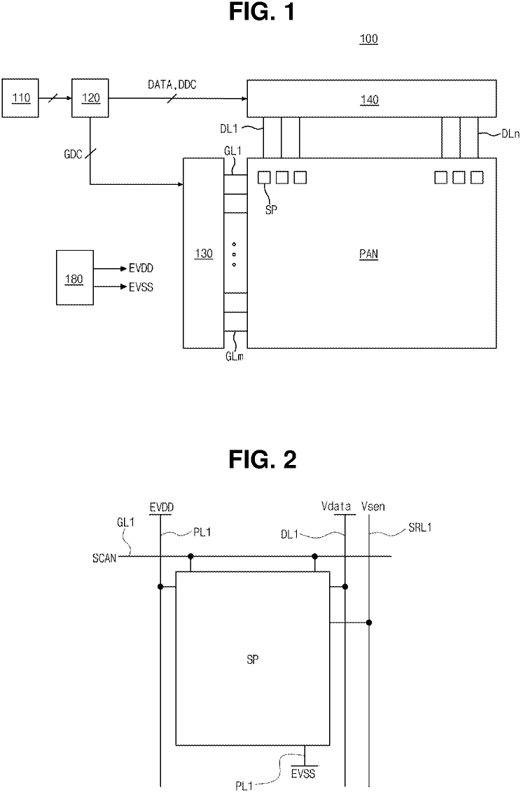

FIG. 1 is a schematic block diagram of an organic light emitting display device according to the present disclosure, and FIG. 2 is a schematic block diagram of a sub-pixel of an organic light emitting display device according to the present disclosure.

As shown in FIG. 1, the organic light emitting display device 100 includes an image processing unit 110, a timing control unit, e.g., a timing controller, 120, a gate driving unit, e.g., a gate driver, 130, a data driving unit, e.g., a data driver, 140, a power supply unit 180 and a display panel PAN.

The image processing unit 110 outputs a driving signal for driving various elements together with image data supplied from the outside. For example, the driving signal output from the image processing unit 110 may include a data enable signal, a vertical synchronization signal, a horizontal synchronization signal, and a clock signal.

The timing control unit 120 receives the driving signal and the image data from the image processing unit 102. The timing control unit 120 outputs a gate timing control signal GDC for controlling the operation timing of the gate driving unit 130 and a data timing control signal DDC for controlling the operation timing of the data driving unit 140 based on the driving signal input from the image processing unit 110.

The gate driving unit 130 outputs a scan signal to the display panel PAN in response to the gate timing control signal GDC supplied from the timing control unit 120. The gate driving unit 130 outputs the scan signal through a plurality of gate lines GL1 to GLm. In this case, the gate driving unit 130 may be formed in the form of an integrated circuit (IC), but it is not limited thereto. In particular, the gate driving unit 130 may have a gate-in-panel (GIP) structure formed by directly stacking TFTs on a substrate inside the organic light emitting display device 100. The GIP may include a plurality of circuits such as a shift register and a level shifter.

The data driving unit 140 outputs a data voltage to the display panel PAN in response to the data timing control signal DDC input from the timing control unit 120. The data driving unit 140 samples and latches the digital data signal DATA supplied from the timing control unit 120 to convert it into an analog data voltage based on a gamma voltage. The data driving unit 140 outputs the data voltage through a plurality of data lines DL1 to DLn. In this case, the data driving unit 140 may be mounted on the top surface of the display panel PAN in the form of the IC or may be formed by stacking various patterns and layers directly on the display panel PAN, but it is not limited thereto.

The power supply unit 180 outputs a high potential driving voltage EVDD and a low potential driving voltage EVSS and supplies them to the display panel PAN. The high potential driving voltage VDD and the low potential driving voltage EVSS are supplied to the display panel PAN through a power line. In this case, the voltage output from the power supply unit 180 may be output to the data driving unit 140 or the gate driving unit 130 to be used for driving them.

The display panel PAN displays an image corresponding to the data voltage and the scan signal supplied from the data driving unit 140 and the gate driving unit 130 and the power supplied from the power supply unit 180.

The display panel PAN includes a plurality of sub-pixels SP and displays an image. The sub-pixel SP includes a red sub-pixel, a green sub-pixel, and a blue sub-pixel, or a white (W) sub-pixel, a red (R) sub-pixel, and a green (G) sub-pixel and a blue (B) sub-pixel. In this case, the W, R, G, and B sub-pixels SP may all have the same area, but may also have different areas.

As shown in FIG. 2, one sub-pixel SP may be connected to a gate line GL1, a data line DL1, a sensing voltage readout line SRL1 and a power supply line PL1. The number of transistors and capacitors in the sub-pixel SP as well as a driving method of the sub-pixel SP are determined according to a circuit configuration.

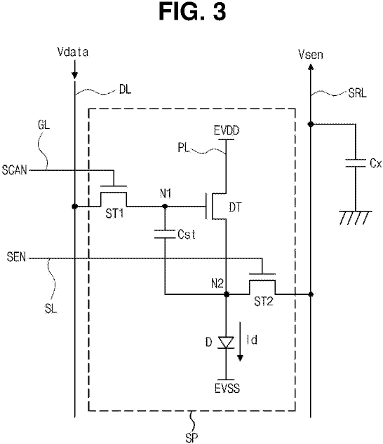

FIG. 3 is a schematic circuit diagram of a sub-pixel of an organic light emitting display device of the present disclosure.

As shown in FIG. 3, the organic light emitting display device 100 according to the present disclosure includes a gate line GL, a data line DL, a power line PL and a sensing line SL crossing each other to define a sub-pixel SP, and the sub-pixel SP includes a driving thin film transistor (TFT) DT, an organic light emitting diode (OLED) D, a storage capacitor Cst, a first switching TFT ST1, and a second switching TFT ST2.

The OLED D includes a first electrode connected to a second node N2, a second electrode connected to an input terminal of the low potential driving voltage EVSS, and an organic light emitting layer positioned between the first electrode and the second electrode.

The driving TFT DT controls the current Id flowing through the OLED D according to the gate-source voltage Vgs. The driving TFT DT includes a gate electrode connected to a first node N1, a source electrode connected to the power line PL to receive the high potential driving voltage EVDD, and a drain electrode connected to the second node N2.

The storage capacitor Cst is connected between the first node N1 and the second node N2.

The first switching TFT ST1 applies the data voltage Vdata charged to the data line DL into the first node N1 in response to the gate signal SCAN when the display panel PAN is driven, so that the driving TFT DT is turned on. At this time, the first switching TFT ST1 includes a gate electrode connected to the gate line GL to receive the scan signal SCAN, a source electrode connected to the data line DL to receive the data voltage Vdata, and a drain electrode connected to the first node N1.

The second switching TFT ST2 stores the source voltage of the second node N2 into a sensing capacitor Cs of the sensing voltage readout line SRL by switching the current between the second node N2 and the sensing voltage readout line SRL in response to the sensing signal SEN. The second switching TFT ST2 resets the source voltage of the driving TFT DT into an initializing voltage Vpre by switching the current between the second node N2 and the sensing voltage readout line SRL in response to the sensing signal SEN when the display panel PAN is driven. In the second switching TFT ST2, the gate electrode is connected to the sensing line SL, the drain electrode is connected to the second node N2, and the source electrode is connected to the sensing voltage readout line SRL.

In FIG. 3, the organic light emitting display device having a 3T1C structure including three TFTs (T) and one storage capacitor (C) has been exemplified and described. However, a structure of the organic light emitting display device of the present disclosure is not limited thereto. The organic light emitting display device may have a structure of 4T1C, 5T1C, 6T1C, 7T1C, or 8T1C.

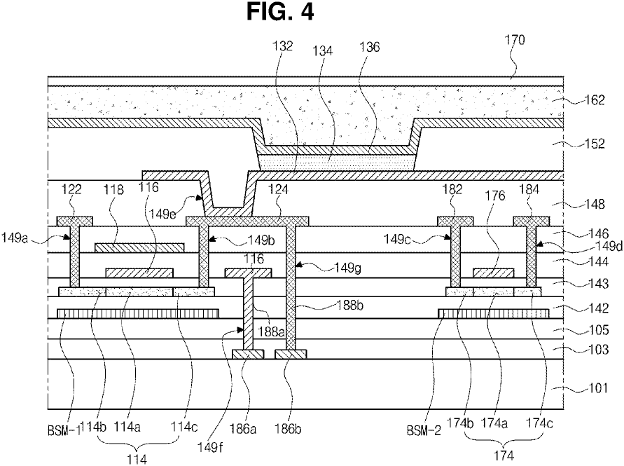

FIG. 4 is a schematic cross-sectional view of an organic light emitting display device according to a first embodiment of the present disclosure.

As shown in FIG. 4, the driving TFT DT and the switching TFT ST are disposed on a first substrate 105. Although the driving TFT DT and one switching TFT ST are shown, this is for convenience of description. A plurality of switching TFTs ST may be disposed on the first substrate 105.

The driving TFT DT includes a first semiconductor layer 114, a first gate electrode 116, a first source electrode 122 and a first drain electrode 124. The first semiconductor layer 114 is disposed on a buffer layer 142 formed on the first substrate 105, and a gate insulating layer 143 covers the first semiconductor layer 114. The first gate electrode 116 is disposed on the gate insulating layer, and an interlayer insulating layer 144 covers the first gate electrode 116. The first source electrode 122 and the first drain electrode 124 are disposed on a passivation layer 146.

A storage electrode 118 is disposed on the interlayer insulating layer 144 to overlap the first gate electrode 116, and the passivation layer 146 covers the storage electrode 118. The storage electrode 118 overlaps the first gate electrode 116 and is positioned between the first source electrode 122 and the first drain electrode 124.

The interlayer insulating layer 144 and the passivation layer 146 are disposed between the first gate electrode 116 and each of the first source and drain electrodes 122 and 124 and between the second gate electrode 176 and each of the second source and drain electrodes 182 and 184. Alternatively, the first source and drain electrodes 122 and 124 and the second source and drain electrodes 182 and 184 may be disposed on the interlayer insulating layer 144 without the passivation layer 146 when the storage electrode 118 is omitted.

The first substrate 105 may be a flexible plastic substrate. For example, the first substrate 105 may be formed of PI (polyimide), PET (polyethylene terephthalate), PEN (polyethylene naphthalate), PC (polycarbonate), PES (polyethersulfone), PAR (polyarylate), PSF (polysulfone) or COC (cyclic-olefin copolymer). Alternatively, the first substrate 105 may be a thin glass substrate.

The buffer layer 142 serves to protect the TFTs formed from impurities such as alkali ions leaking from the first substrate 105 or to block outer moisture. The buffer layer 142 may be a single layer made of silicon oxide (SiOx) or silicon nitride (SiNx) or a multilayer thereof.

The first semiconductor layer 114 may be made of an amorphous semiconductor material such as amorphous silicon (a-Si), a crystalline semiconductor material such as polysilicon (p-Si), or an oxide semiconductor such as indium gallium zinc oxide (IGZO). In this case, the first semiconductor layer 114 includes a first channel region 114a in a center and a first source region 114b and a first drain region 114c as a doping region at both sides.

The first gate electrode 116 may be formed of a single layer or a plurality of layers made of a metal such as Cr, Mo, Ta, Cu, Ti, Al, or an Al alloy, but it is not limited thereto.

The interlayer insulating layer 144 may be formed of a single layer made of an inorganic material such as SiNx or SiOx or a plurality of layers thereof.

The storage electrode 118 may be formed of a metal, but it is not limited thereto.

The passivation layer 146 may be formed of an organic material such as photoacryl, but it is not limited thereto. The passivation layer 146 may include a plurality of layers including an inorganic layer and an organic layer.

The first source electrode 122 and the first drain electrode 124 may be formed of a single layer or a plurality of layers made of a metal such as Cr, Mo, Ta, Cu, Ti, Al, or an Al alloy, but it is not limited thereto.

The first source electrode 122 and the first drain electrode 124 respectively have an ohmic contact to the first source region 114b and the first drain region 114c of the first semiconductor layer 114 though a first contact hole 149a and a second contact hole 149b formed in the gate insulating layer 143, the interlayer insulating layer 144, and the passivation layer 146.

The switching TFT ST includes a second semiconductor layer 174 on the buffer layer 142, a second gate electrode 176 on the gate insulating layer 143, and a second source electrode 182 and a second drain electrode 184 on the passivation layer 146.

The second semiconductor layer 174 may be made of an amorphous semiconductor material such as amorphous silicon (a-Si), a crystalline semiconductor material such as polysilicon (p-Si), or an oxide semiconductor such as indium gallium zinc oxide (IGZO). The second semiconductor layer 174 includes a second channel region 174a in a center and a second source region 174b and a second drain region 174c as a doping region at both sides. The second semiconductor layer 174 of the switching TFT ST and the first semiconductor layer 114 of the driving TFT DT include the same material or different materials.

Since the driving TFT DT and the switching TFT ST have different functions, electrical characteristics for performing these functions may also be different. The driving TFT DT controls the current supplied to the OLED so that light is emitted from the organic light emitting layer 134 to display an image. Therefore, for sufficient grayscale expression of an image, the driving TFT DT must have advantageous electrical characteristics for grayscale expression. On the other hand, since the switching TFT ST supplies the gate signal to the driving TFT DT, the switching TFT ST mush have fast switching speed, i.e., on/off response speed, in order to implement a high-quality image.

In FIG. 4, the driving TFT DT and the switching TFT ST are formed in the same structure. However, in order to have different electrical characteristics, the driving TFT DT and the switching TFT ST may be formed in different structures. In addition, the driving TFT DT may use a crystalline semiconductor material in the first semiconductor layer 114, and the switching TFT ST may use an oxide semiconductor material in the second semiconductor layer 174. Alternatively, the driving TFT DT and the switching TFT ST include the same semiconductor material, while the driving TFT DT and the switching TFT ST have different electrical characteristics by controlling an s-factor.

The second gate electrode 176 may be formed of a single layer or a plurality of layers made of a metal such as Cr, Mo, Ta, Cu, Ti, Al, or an Al alloy, but it is not limited thereto. The first gate electrode 116 and the second gate electrode 176 may include the same metallic material or different metallic materials.

The second source electrode 182 and the second drain electrode 184 may be formed of a single layer or a plurality of layers made of a metal such as Cr, Mo, Ta, Cu, Ti, Al, or an Al alloy, but it is not limited thereto. The first source electrode 122, the first drain electrode 124, the second source electrode 182 and the second drain electrode 184 may include the same metallic material or different metallic materials.

The second source electrode 182 and the second drain electrode 184 respectively have an ohmic contact to the second source region 174b and the second drain region 174c of the second semiconductor layer 174 though a third contact hole 149c and a fourth contact hole 149d formed in the gate insulating layer 143, the interlayer insulating layer 144, and the passivation layer 146.

A planarization layer 148 is formed on the substrate 105 on which the driving TFT DT and the switching TFT ST are disposed. The planarization layer 148 may be formed of an organic material such as photoacryl. Alternatively, the planarization layer 148 may have a multi-layered structure including an inorganic layer and an organic layer. A fifth contact hole 149e exposing the first drain electrode 124 of the driving transistor DT is formed in the planarization layer 148.

The first electrode 132 electrically connected to the first drain electrode 124 of the driving transistor DT through the fifth contact hole 149e is formed on the planarization layer 148. The first electrode 132 is separated in each sub-pixel. The first electrode 132 is connected to the first drain electrode 124 of the driving transistor DT, and an image signal is applied to the first electrode 132. In a bottom emission type organic light emitting display device, the first electrode 132 includes a transparent conductive layer being formed of a transparent conductive material, e.g., indium tin oxide (ITO) or indium zinc oxide (IZO). In a top emission type organic light emitting display device, the first electrode 132 may further include a reflection layer being formed of silver (Ag) or aluminum-palladium-copper (APC) alloy. In this instance, the first electrode 132 may have a triple-layered structure of ITO/Ag/ITO or ITO/APC/ITO. Alternatively, in the top emission organic light emitting display device, the first electrode 132 may include a metallic material such as Ca, Ba, Mg, Al, Ag, or their alloys and may have a single-layered structure or a multi-layered structure. Namely, the first electrode 132 is a transparent electrode in the bottom emission type organic light emitting display device or a reflective electrode in the top emission type organic light emitting display device. The first electrode 132 is one of an anode and a cathode.

A bank layer 152 is disposed at a boundary between each sub-pixel SP and on the planarization layer 148. The bank layer 152 is a type of barrier wall. Each sub-pixel SP is partitioned by the bank layer 152 so that color mixing between adjacent sub-pixel SP can be prevented.

An organic light emitting layer 134 is formed on the first electrode 132 and on a partial region of the inclined surface of the bank layer 152. The organic light emitting layer 134 may include an R-organic light emitting layer, which is formed in the red sub-pixel to emit red light, a G-organic light emitting layer, which is formed in the green sub-pixel to emit green light, and a B-organic light emitting layer, which is formed in the blue sub-pixel to emit blue light. In addition, the organic light emitting layer 134 may further include a W-organic light emitting layer emitting white light.

Each organic light emitting layer 134 includes a light emitting layer, e.g., an emitting material layer, a hole injection layer, a hole transporting layer, an electron transporting layer and an electron injection layer. The hole and the electron are injected toward the light emitting layer by the hole injection layer and the electron injection layer and are transported into the light emitting layer by the hole transporting layer and the electron transporting layer respectively.

A second electrode 136 is formed on the organic light emitting layer 134. In the top emission type organic light emitting display device, the second electrode 136 is a transparent electrode (or a semi-transparent electrode). The second electrode 136 may include a metallic material such as Ca, Ba, Mg, Al, Ag, or their alloys and have a thin profile to transmit a visible light. Alternatively, the second electrode 136 may include a transparent conductive material, e.g., ITO or IZO. In the bottom emission type organic light emitting display device, the second electrode 136 includes a metallic material such as Ca, Ba, Mg, Al, Ag, or their alloys and is a reflective electrode. The second electrode 136 is the other one of the anode and the cathode.

An encapsulation layer 162 is formed on the second electrode 136. The encapsulation layer 162 may have a single-layered structure of an inorganic layer, a double-layered structure of an inorganic layer and an organic layer, or a triple-layered structure of an inorganic layer, an organic layer and an inorganic layer. The inorganic layer may include an inorganic material such as SiNx or SiX, but it is not limited thereto. The organic layer may include an organic material such as polyethylene terephthalate, polyethylene naphthalate, polycarbonate, polyimide, polyethylene sulfonate, polyoxymethylene, polyarylate, or their mixtures, but it is not limited thereto.

A second substrate 170 is disposed on the encapsulation layer 162 and is attached by an adhesive layer (not shown). As the adhesive layer, any material may be used as long as it has good adhesion and good heat resistance and water resistance. In the organic light emitting display device of the present disclosure, a thermosetting resin, such as an epoxy compound, an acrylate compound, or an acrylic rubber, may be used for the adhesive layer. Alternatively, a photocurable resin may be used for the adhesive layer. In this case, the adhesive layer is cured by irradiating light such as ultraviolet rays to the adhesive layer.

The first substrate 105 and the second substrate 170 are attached by the adhesive layer. In addition, the adhesive layer may serve as an encapsulant for preventing moisture penetration into the organic light emitting display device.

The second substrate 170 is an encapsulation cap for encapsulating the organic light emitting display device. A protection film such as a polystyrene (PS) film, a polyethylene (PE) film, a polyethylene naphthalate (PEN) film, or a polyimide (PI) film, or a thin glass may be used for the second substrate 170.

The organic light emitting display device as described above is manufactured on a support substrate 101. Namely, after attaching the first substrate 105 on the support substrate 101 by a sacrificial layer 103, the driving TFT DT, the switching TFT ST and the OLED are stacked on the first substrate 105.

The support substrate 101 may be a glass substrate, but it is not limited thereto. In addition, the sacrificial layer 103 may be formed of amorphous silicon, but it is not limited thereto. Alternatively, the sacrificial layer 103 may be formed of a polymer, such as polyimide, a metal, an adhesive, or the like.

When the first substrate 105 is formed of a plastic material, the first substrate 105 may be formed in a film shape and attached to the support substrate 101 by the sacrificial layer 103. Alternatively, the first substrate 105 may be formed by coating and curing a liquid phase material on the sacrificial layer 103.

First and second aging voltage lines 186a and 186b are formed on the upper surface of the support substrate 101, and the sacrificial layer 103 is formed on the support substrate 101 and the first and second aging voltage lines 186a and 186b to cover the first and second aging voltage lines 186a and 186b. In addition, a sixth contact hole 149f is formed in the sacrificial layer 103, the first substrate 105, the buffer layer 142 and the gate insulating layer 143, and a first aging voltage supply line 188a is formed in the sixth contact hole 149f so that the first aging voltage line 186a and the first gate electrode 116 are electrically connected to each other by the first aging voltage supply line 188a. As a result, an aging voltage applied to the first aging voltage line 186a is supplied to the first gate electrode 116. In FIG. 4, for convenience of explanation, the first gate electrode 116 is shown by two-separated parts. However, two-separated parts are integrated as one-body.

The first aging voltage supply line 188a is formed of a metallic material. The first aging voltage supply line 188a and the first gate electrode 116 are formed of the same metallic material or different metallic materials.

A seventh contact hole 149g is formed in the sacrificial layer 103, the first substrate 105, the buffer layer 142, the gate insulating layer 143 and the passivation layer 146, and a second aging voltage supply line 188b is formed in the seventh contact hole 149g so that the second aging voltage line 186b and the first drain electrode 124 are electrically connected to each other by the second aging voltage supply line 188b. As a result, an aging voltage applied to the second aging voltage line 186b is supplied to the first drain electrode 124.

The second aging voltage supply line 188b is formed of a metallic material. The second aging voltage supply line 188b and the first drain electrode 124 are formed of the same metallic material or different metallic materials.

The first and second aging voltage lines 186a and 186b are electrically connected to the first gate electrode 116 and the first drain electrode 124 through the first and second aging voltage supply lines 188a and 188b, respectively. As a result, an aging voltage is applied to the driving TFT DT.

In general, when a TFT is driven at room temperature for a long time, a leakage current occurs due to moving electrons in the PN junction portion. An afterimage occurs on the screen when the organic light emitting display device is driven due to the leakage current.

In the organic light emitting display device of the present disclosure, by applying an aging voltage to the driving TFT DT through the first and second aging voltage lines 186a and 186b to age the driving TFT DT, the leakage current can be reduced.

In particular, in the organic light emitting display device of the present disclosure, the first and second aging voltage lines 186a and 186b are formed under the first substrate 105, and the first and second aging voltage lines 186a and 186b are directly connected to the first gate electrode 116 and the first drain electrode 124 of the driving TFT DT through the first and second aging voltage supply lines 188a and 188b, respectively. As a result, the aging voltage is directly applied to the driving TFT DT to age the driving TFT DT. Hereinafter, the reason of forming the first and second aging voltage lines 186a and 186b and first and second aging voltage supply lines 188a and 188b and directly applying the aging voltage into the driving TFT DT will be described in detail.

Aging of the TFT may be performed for all TFTs disposed in the organic light emitting display device, but may be performed only on the driving TFT DT, which substantially determines the image quality of the organic light emitting display device. A method of aging the driving TFT DT will be described.

Referring back to FIG. 3, the conventional aging is performed by applying an aging voltage to the gate electrode and the drain electrode of the driving TFT DT through the data line DL and the power supply line PL, respectively. In the conventional aging method, since the aging voltage is supplied to the data line DL and the power line PL, the aging voltage is applied to the driving TFT DT through the first switching TFT ST1.

Accordingly, since the aging voltage is applied not only to the TFT being the aging target but also to other TFTs, not only the electrical characteristic change of other TFTs but also the defect in other TFTs may occur by the applied aging voltage. For example, when other TFTs are driven, a difference of on-current occurs so that the corresponding TFT may be burned.

This problem occurs more and more as the number of TFTs increases. Namely, as the organic light emitting display device has a structure of 4T1C, 5T1C, 6T1C, 7T1C or 8T1C, the number of TFTs, to which an aging voltage is applied, is increased. Accordingly, the number of the TFTs having the electrical characteristic change and/or the defect by the applied aging voltage is increased, and the possibility that the organic light emitting display device becomes defective is increased.

In the organic light emitting display device of the present disclosure, since the aging voltage is directly applied to the driving TFT DT through the first and second aging voltage lines 186a and 186b and the first and second aging voltage supply lines 188a and 188b but not through the data line DL and the power line PL, other TFTs are not affected by the aging voltage. Accordingly, the problem, e.g., burning, by the aging voltage can be prevented.

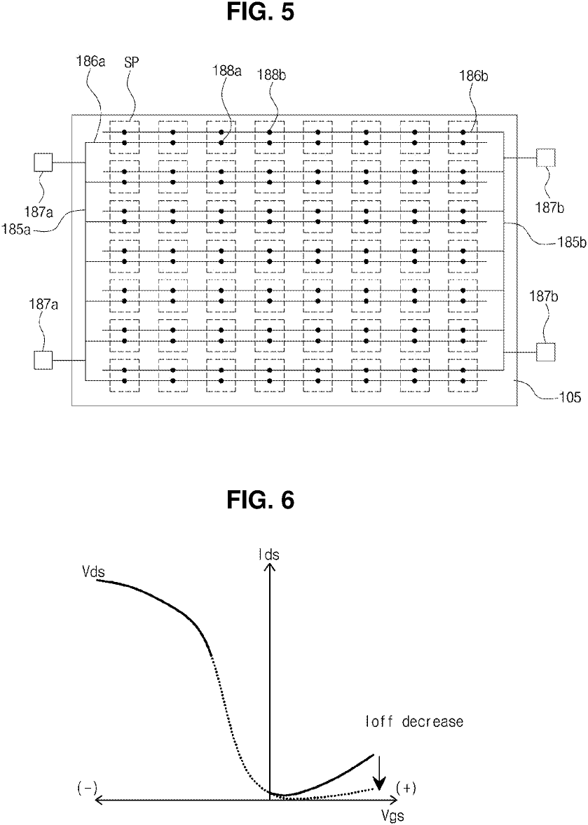

FIG. 5 is a schematic plan view illustrating a structure of first and second aging voltage lines.

As shown in FIG. 5, a plurality of first and second aging voltage lines 186a and 186b are arranged in a horizontal direction, respectively. The first and second aging voltage lines 186a and 186b are electrically connected to the first and second aging voltage supply lines 188a and 188b of each sub-pixel SP, respectively.

The first aging voltage lines 186a are connected to first connection lines 185a, and the second aging voltage lines 186b are connected to second connection lines 185b. A first aging pad 187a and a second aging pad 187b are formed at the first and second connecting lines 185a and 185b, respectively. Aging voltage applying means such as a probe is in contact with the first and second aging pads 187a and 187b, and the aging voltage is applied from the outside. The aging voltage applied to each of the first and second aging pads 187a and 187b is transmitted through the plurality of first and second aging voltage lines 186a and 186b and is applied to the first gate electrode 116 and the second drain electrode 124 of the driving TFT DT through the first and second aging voltage supply lines 188a and 188b.

As described above, in the organic light emitting display device of the present disclosure, by applying the aging voltage to each of the first and second aging pads 187a and 187b, the aging voltage can be simultaneously supplied to the driving TFT DT of the entire display device 100. Accordingly, the driving TFT DT can be quickly and accurately aged.

In FIG. 5, two first aging pads 187a and two second aging pads 187b are formed on the first and second connection lines 185a and 185b, respectively. Alternatively, one first aging pad 187a and one second aging pad 187b or three or more first aging pads 187a and three or more second aging pads 187b may be formed. For example, when the area of the display device is small, the aging voltage can be supplied to the driving TFTs DT of all sub-pixels without delay even when one first aging pads 187a and one second aging pads 187b are formed. Alternatively, when the area of the display device is increased, the number of the first and second aging pads 187a and 187b is increased, so that the aging voltage is supplied to the driving TFTs DT of all the sub-pixels.

In addition, the first and second aging pads 187a and 187b are formed in a rectangular shape in FIG. 5. Alternatively, each of the first and second aging pads 187a and 187b may be formed to have various shapes. In addition, various methods may be used for applying the aging voltage to the first and second aging pads 187a and 187b.

In addition, in FIG. 5, the first and second connection lines 185a and 185b extend in the vertical direction, i.e., y-direction, from opposite sides, respectively, and the plurality of first and second aging voltage lines 186a and 186b respectively extend in the horizontal direction, i.e., x-direction. Alternatively, the first and second connection lines 185a and 185b may extend in the horizontal direction, i.e., x-direction, from opposite sides, respectively, and the plurality of first and second aging voltage lines 186a and 186b may respectively extend in the vertical direction, i.e., y-direction.

Meanwhile, as will be described later in detail, the support substrate 101 is separated (released) from the first substrate 105, and at this time, the first and second aging voltage lines 186a and 186b are also separated and removed. As a result, only the first and second aging voltage supply lines 188a and 188b remain on a lower surface of the first substrate 105.

FIG. 6 is a view illustrating an electrical property of a driving TFT in the organic light emitting display device.

In FIG. 6, a straight line shows a current of the driving TFT DT without aging, and a dotted line shows the current of the driving TFT DT with aging. As shown in FIG. 6, in the driving TFT DT according to the present disclosure, the off current is decreased as aging progresses. Since the problem of the leakage current in the driving TFT DT can be prevented as the off current decreases, the image quality deterioration such as an afterimage can be prevented.

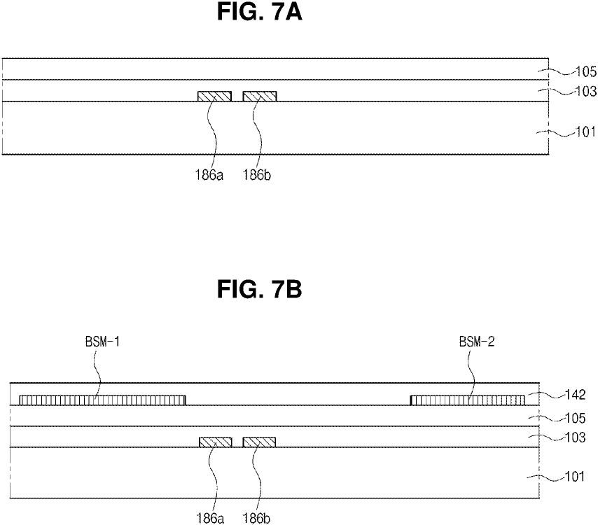

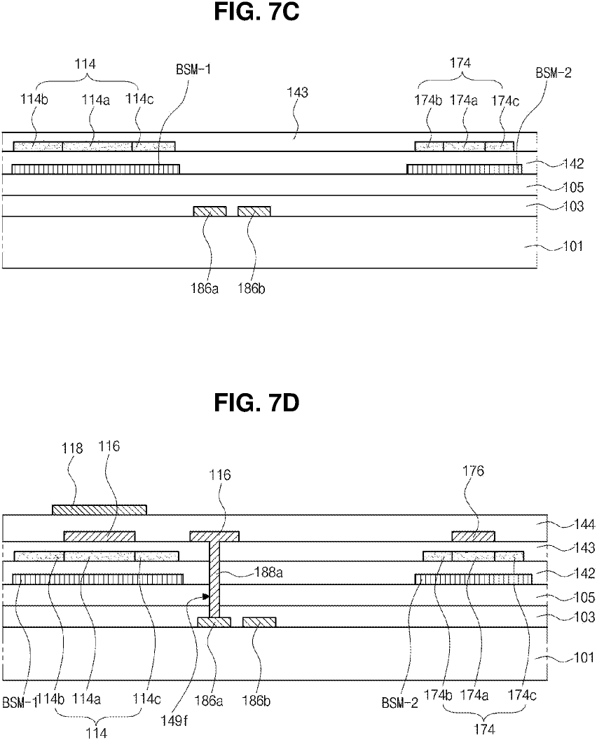

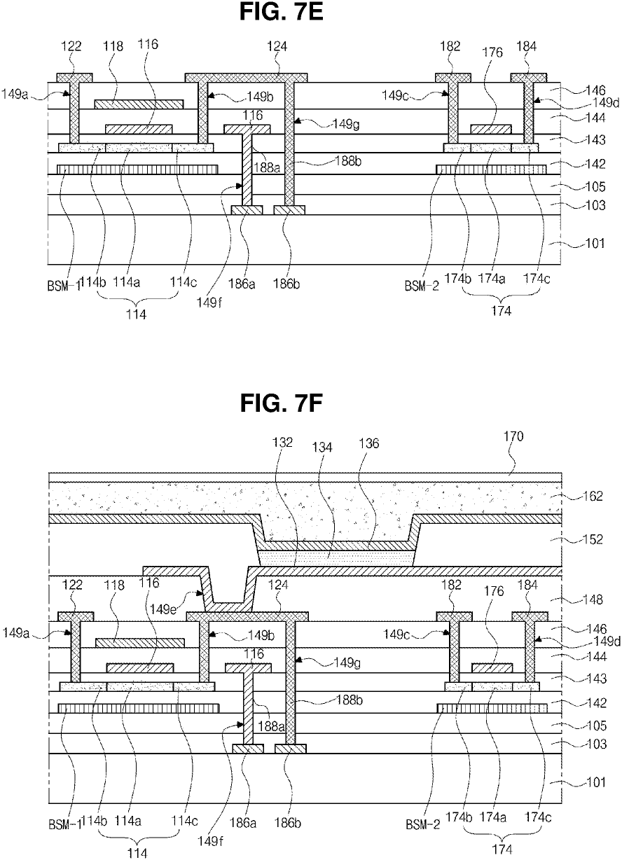

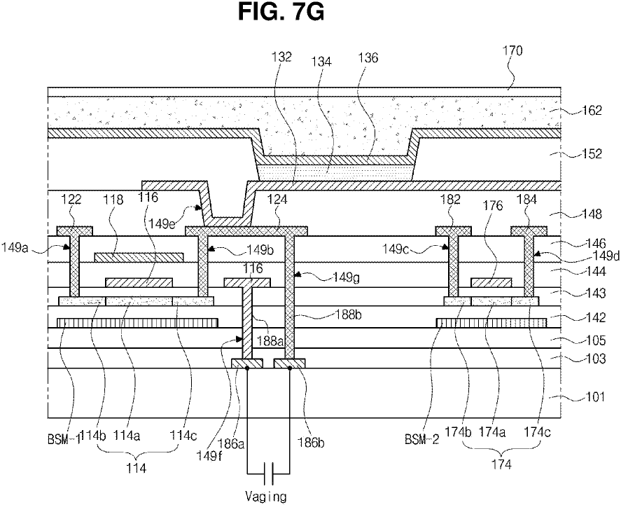

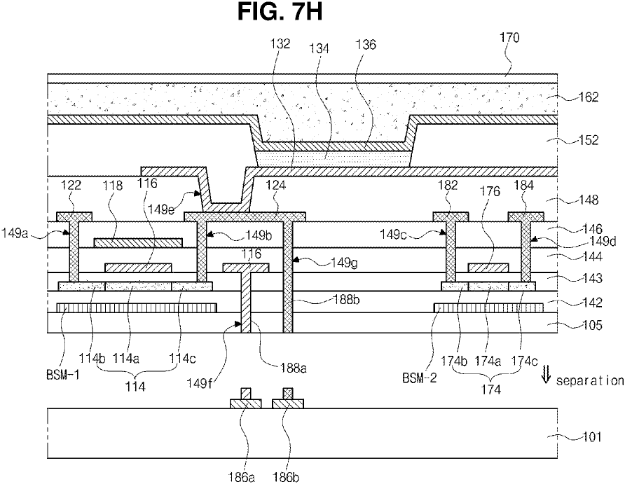

FIGS. 7A to 7I are schematic cross-sectional view illustrating a method of fabricating the organic light emitting display device according to the first embodiment of the present disclosure.

As shown in FIG. 7A, a metallic material is stacked (e.g., deposited) on a hard and transparent support substrate 101 such as glass by a sputtering method and etched to form the first and second aging voltage lines 186a and 186b arranged in a horizontal direction (x-direction) or a vertical direction (y-direction). After the sacrificial layer 103 of amorphous silicon is formed over the entire support substrate 101 by a chemical vapor deposition (CVD) method, the first substrate 105 is formed.

In this case, the first substrate 105 is formed on the sacrificial layer 103 by attaching a plastic film formed of a plastic material, e.g., PI (polyimide), PET (polyethylene terephthalate), PEN (polyethylene naphthalate), PC (polycarbonate), PES (polyethersulfone), PAR (polyarylate), PSF (polysulfone), or cyclic-olefin copolymer (COC) or coating and curing the plastic material in a liquid phase.

Next, as shown in FIG. 7B, a metallic material is stacked by sputtering and etched to form a first lower blocking metal layer BSM_1 and a second lower blocking metal layer BSM_2. The buffer layer 142 having a single-layered structure or a multi-layered structure is formed on the first lower blocking metal layer BSM_1 and the second lower blocking metal layer BSM_2 by stacking an inorganic material, e.g., SiOx or SiNx, by a CVD (Chemical Vapor Deposition) method or the like.

Next, as shown in FIG. 7C, a semiconductor material layer of a semiconductor material is stacked and etched to form the first and second semiconductor layers 114 and 174 on the buffer layer 142. For example, the semiconductor material is one of an oxide semiconductor, e.g., IGZO, an amorphous semiconductor, e.g., amorphous silicon (a-Si), and a crystalline semiconductor, e.g., polysilicon (p-Si). The impurities are doped into both sides of each of the first and second semiconductor layers 114 and 174 to form the first source and drain regions 114b and 114c of the first semiconductor layer 114 and the second source and drain regions 174b and 174c of the second semiconductor layer 174. A center of the first semiconductor layer 114 and a center of the second semiconductor layer 174 are respectively defined as the first and second channel regions 114a and 174a. An inorganic material, e.g., SiOx or SiNx, is deposited as a single layer or multi-layers by the CVD method to form the gate insulating layer 143 on the first and second semiconductor layers 114 and 174.

Next, as shown in FIG. 7D, the sacrificial layer 103, the first substrate 105, the buffer layer 142 and the gate insulating layer 143 are etched to form the sixth contact hole 149f, and a metallic material is stacked on the gate insulating layer 143 and etched to form the first gate electrode 116, the second gate electrode 176 and the first aging voltage supply line 188a. The first aging voltage supply line 188a is branched from the first gate electrode 116 and extends into the first aging voltage line 186a through the sixth contact hole 149f. Namely, the first aging voltage supply line 188a is formed by depositing the metallic material in the sixth contact hole 149f. Accordingly, the first aging voltage supply line 188a is simultaneously formed as the first and second gate electrodes 116 and 176.

Alternatively, the first aging voltage supply line 188a may be formed by a different process than the first and second gate electrode 116 and 176. For example, after a first metallic material is stacked in the sixth contact hole 149f to form the first aging voltage supply line 188a, a second metallic material is stacked and etched to form the first and second gate electrodes 116 and 176.

Next, an inorganic material is stacked by a single layer or multi-layers to form the interlayer insulating layer 144, and a metallic material is stacked and etched to form the storage electrode 118 on the interlayer insulating layer 144. The storage electrode 118 is disposed to overlap or correspond to the first gate electrode 116.

Next, as shown in FIG. 7E, an organic material is stacked (e.g., coated) to form the passivation layer 146 on the storage electrode 118 and the interlayer insulating layer 144. A portion of the gate insulating layer 143, the interlayer insulating layer 144 and the passivation layer 146 corresponding to the first source and drain regions 114b and 114c of the first semiconductor layer 114 and the second source and drain regions 174b and 174c of the second semiconductor layer 174 is etched to form the first, second, third and fourth contact holes 149a, 149b, 149c and 149d. In addition, a portion of the sacrificial layer 103, the first substrate 105, the buffer layer 142, the gate insulating layer 143, the interlayer insulating layer 144 and the passivation layer 146 corresponding to the second aging voltage line 186b is etched to form the seventh contact hole 149g. Next, a metallic material is stacked and etched to form the first source and drain electrodes 122 and 124, the second source and drain electrodes 182 and 184 and the second aging voltage supply line 188b. As a result, the driving TFT DT and the switching TFT ST are formed.

The second aging voltage supply line 188b is formed by depositing the metallic material for the source electrodes 122 and 182 and the drain electrodes 124 and 184 in the seventh contact hole 149g. Accordingly, the second aging voltage supply line 188b is simultaneously formed as the first and second source electrodes 122 and 182 and the first and second drain electrodes 124 and 184.

Alternatively, the second aging voltage supply line 188b may be formed by a different process than the first and second source electrodes 122 and 182 and the first and second drain electrodes 124 and 184. For example, after a first metallic material is stacked in the seventh contact hole 149g to form the second aging voltage supply line 188b, a second metallic material is stacked and etched to form the first and second source electrodes 122 and 182 and the first and second drain electrodes 124 and 184.

Next, as shown in FIG. 7F, an inorganic insulating material is stacked and etched to form the planarization layer 148 including the fifth contact hole 149e. Namely, the inorganic insulating material layer is etched to form the fifth contact hole 149e exposing the first drain electrode 124 of the driving TFT DT. Next, a transparent conductive material, e.g., ITO or IZO, is stacked and etched to form the first electrode 132 on the planarization layer 148. The first electrode 132 is electrically connected to the first drain electrode 124 of the driving TFT DT through the fifth contact hole 149e.

Next, the bank layer 152 including an opening is formed on the planarization layer 148. The bank layer 152 covers an edge of the first electrode 132 and exposes a center of the first electrode 132. The organic light emitting layer 134 is formed by coating an organic emitting material in the opening of the bank layer 152. Next, a metallic material is deposited with a thickness of several tens nanometers by a sputtering method and etched to form the second electrode 136 on the organic light emitting layer 134.

Next, an inorganic material, e.g., SiNx or SiX, and an organic material, e.g., polyethylene terephthalate, polyethylene naphthalate, polycarbonate, polyimide, polyethylene sulfonate, polyoxymethylene or polyarylate, are stacked to form the encapsulation layer 162 on the second electrode 136. Next, an adhesive layer (not shown) is coated on the encapsulation layer 162, and the second substrate 170 is placed thereon, and then the adhesive layer is cured.

Next, as shown in FIG. 7G, an aging voltage “Vaging” is applied to the first and second aging voltage lines 186a and 186b so that the aging voltage is applied to the first gate electrode 116 and the first drain electrode 124 through the first and second aging voltage supply lines 188a and 188b. As a result, the driving TFT is aged.

Next, as shown in FIG. 7H, the support substrate 101 which is transparent is separated from the first substrate 105 by irradiating a laser from the side of the support substrate 101. The laser is transmitted to the sacrificial layer 103 through the support substrate 101 so that the uniformity of the interface between the support substrate 101 and the sacrificial layer 103 is degraded or hydrogen is generated at the interface between the support substrate 101 and the sacrificial layer 103. As a result, the bonding energy at the interface is weakened, and the support substrate 101 is separated from the first substrate 105.

A heat may be applied to the sacrificial layer 103 to weaken the bonding energy of the sacrificial layer 103.

Next, as shown in FIG. 7I, a sealing layer (e.g., a sealing pattern) 189a, 189b for sealing the first and second aging voltage supply lines 188a and 188b exposed to the lower surface of the first substrate 105 due to the separation of the support substrate 101 is formed on the lower surface of the first substrate 105. Since the exposed end of the first and second aging voltage supply lines 188a and 188b is blocked by the sealing layer 189a, 189b, the penetration of moisture or foreign substance into the organic light emitting display device through the exposed end of the first and second aging voltage supply lines 188a and 188b is prevented.

The sealing layer 189a, 189b may be formed by depositing an inorganic material, e.g., SiNx or SiX, or coating an organic material, e.g., polyethylene terephthalate, polyethylene naphthalate, polycarbonate, polyimide, polyethylene sulfonate, polyoxymethylene, or polyarylate. In addition, the sealing layer 189a, 189b may be formed by welding.

In FIG. 7I, the sealing layer 189a, 189b is formed as a pattern shape to correspond to the first and second aging voltage supply lines 188a and 188b, respectively. Accordingly, the number of the sealing layer 189a, 189b is equal to the number of the first and second aging voltage supply lines 188a and 188b, respectively. Alternatively, the sealing layer 189a, 189b may be formed as a film shape to correspond to an entire surface of the first substrate 105.

As described above, in the organic light emitting display device of the present disclosure, the driving TFT DT is aged, and the leakage current from the driving TFT DT can be prevented. Accordingly, defects such as an afterimage in the organic light emitting display device can be prevented.

In addition, in the organic light emitting display device of the present disclosure, since the aging voltage is directly applied to the driving TFT through the first and second aging voltage lines and the first and second aging voltage supply lines, but not through the data line and the power line, the affect on other TFTs by the aging voltage can be prevented.

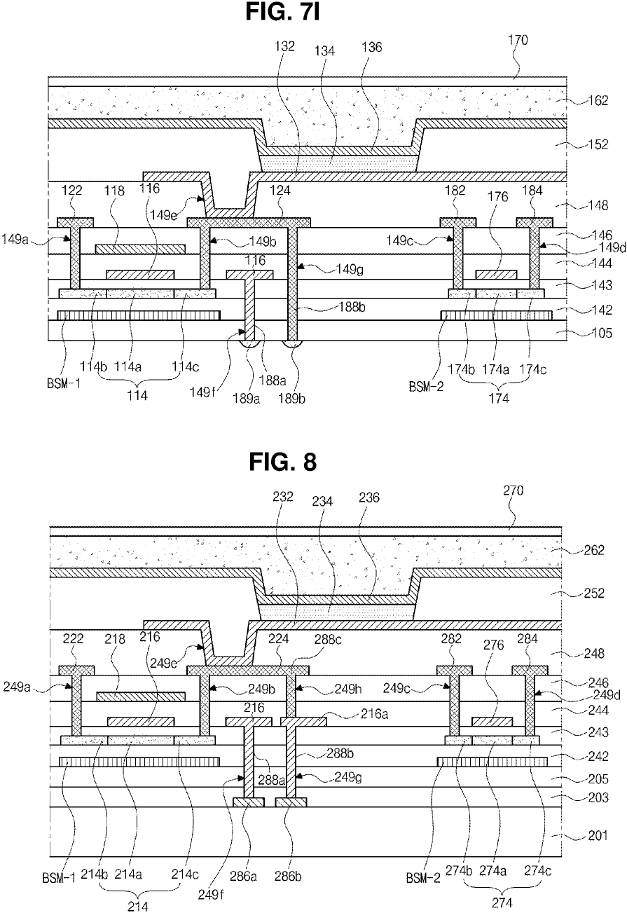

FIG. 8 is a schematic cross-sectional view of an organic light emitting display device according to a second embodiment of the present disclosure. The same configuration as that of the first embodiment shown in FIG. 4 will be omitted or simplified, and the description hereinafter is mainly focused on other configurations.

As shown in FIG. 8, in the organic light emitting display device according to the second embodiment of the present disclosure, the first and second aging voltage lines 286a and 286b are formed on the upper surface of the support substrate 201, the first gate electrode 216 and a metal pattern 216a are formed on the gate insulating layer 243. The metal pattern 216a is formed to be spaced apart from the first gate electrode 216 by a predetermined distance, and is electrically insulated from the first gate electrode 216. The metal pattern 216a may be formed of the same metallic material and by the same process as the first gate electrode 216, but it is not limited thereto. The metal pattern 216a and the first gate electrode 216 may be formed of different metallic material and/or by different processes.

The sixth contact hole 249f is formed in the sacrificial layer 203, the first substrate 205, the buffer layer 242 and the gate insulating layer 243, and the first aging voltage supply line 288a is formed in the sixth contact hole 249f so that the first aging voltage line 286a and the first gate electrode 216 are electrically connected to each other by the first aging voltage supply line 288a. As a result, an aging voltage applied to the first aging voltage line 286a is supplied to the first gate electrode 216. In FIG. 8, for convenience of explanation, the first gate electrode 216 is shown by two-separated parts. However, two-separated parts are integrated as one-body.

A seventh contact hole 249g is formed in the sacrificial layer 203, the first substrate 205, the buffer layer 242 and the gate insulating layer 243, and a second aging voltage supply line 288b is formed in the seventh contact hole 249g so that the second aging voltage line 286b and the metal pattern 216a are electrically connected to each other by the second aging voltage supply line 288b.

An eighth contact hole 249h is formed in the interlayer insulating layer 244 and the passivation layer 246, and a third aging voltage supply line 288c is formed in the eighth contact hole 249h so that the metal pattern 216a and the first drain electrode 224 are electrically connected to each other by the third aging voltage supply line 288c.

Accordingly, the second aging voltage line 286b is electrically connected to the first drain electrode 224 through the second aging voltage supply line 288b, the metal pattern 216a and the third aging voltage supply line 288c, and an aging voltage applied to the second aging voltage line 286b is supplied to the first drain electrode 224.

The first aging voltage supply line 288a may be formed of the same material as the first gate electrode 216. Alternatively, the first aging voltage supply line 288a and the first gate electrode 216 may be formed of different materials. The second aging voltage supply line 288b may be formed of the same material as the metal pattern 216a and the first gate electrode 216. Alternatively, the second aging voltage supply line 288b may be formed of a material being different from that of the metal pattern 216a and the first gate electrode 216. The third aging voltage supply line 288c may be formed of the same material as the first drain electrode 224. Alternatively, the third aging voltage supply line 288c and the first drain electrode 224 may be formed of different materials.

In the organic light emitting display device of the second embodiment of the present disclosure, the first and second aging voltage lines 286a and 286b are formed on the lower surface of the first substrate 205. The first aging voltage line 286a is connected to the first gate electrode 216 of the driving TFT DT through the first aging voltage supply line 288a, and the second aging voltage line 286b is connected to the first drain electrode 224 of the driving TFT DT through the second aging voltage supply line 288b, the metal pattern 216a and the third aging voltage supply line 288c. The aging voltage is applied to the driving TFT DT so that the driving TFT DT is aged.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

What is claimed is:

1. An organic light emitting display device, comprising:
a first substrate including a plurality of sub-pixels;
a thin film transistor in each of the plurality of sub-pixels and on the first substrate;
an organic light emitting diode in each of the plurality of sub-pixels and on the first substrate; and
an aging voltage supply line extending from a lower surface of the first substrate to a portion of the thin film transistor and supplying an aging voltage to the thin film transistor.

2. The organic light emitting display device according to claim 1, wherein the thin film transistor includes:
a semiconductor layer over the first substrate and under a gate insulating layer;
a gate electrode on the gate insulating layer and under an interlayer insulating layer; and
a source electrode and a drain electrode on the interlayer insulating layer.

3. The organic light emitting display device according to claim 2, wherein the aging voltage supply line includes:
a first aging voltage supply line in a first contact hole through the first substrate and the gate insulating layer and connected to the gate electrode; and
a second aging supply line in a second contact hole through the first substrate, the gate insulating layer and the interlayer insulating layer and connected to the drain electrode.

4. The organic light emitting display device according to claim 3, wherein the first aging voltage supply line is formed of the same material as the gate electrode.

5. The organic light emitting display device according to claim 3, wherein the second aging voltage supply line is formed of the same material as the drain electrode.

6. The organic light emitting display device according to claim 2, further comprising a metal pattern on the gate insulating layer.

7. The organic light emitting display device according to claim 6, wherein the aging voltage supply line includes:
a first aging voltage supply line in a first contact hole through the first substrate and the gate insulating layer and connected to the gate electrode;
a second aging supply line in a second contact hole through the first substrate and the gate insulating layer and connected to the metal pattern; and
a third aging supply line in a third contact hole through the interlayer insulating layer and connecting the metal pattern and the drain electrode.

8. The organic light emitting display device according to claim 7, wherein the first aging voltage supply line is formed of the same material as the gate electrode.

9. The organic light emitting display device according to claim 7, wherein the second aging voltage supply line and the metal pattern are formed of the same material as the gate electrode.

10. The organic light emitting display device according to claim 7, wherein the third aging voltage supply line is formed of the same material as the drain electrode.

11. The organic light emitting display device according to claim 1, wherein an end of the aging voltage supply line is exposed at the lower surface of the first substrate.

12. The organic light emitting display device according to claim 11, further comprising a sealing layer disposed on the lower surface of the first substrate and sealing the end of the aging voltage supply line.

13. The organic light emitting display device according to claim 12, wherein the sealing layer has a pattern shape corresponding to the end of the aging voltage supply line.

14. The organic light emitting display device according to claim 12, wherein the sealing layer has a film shape corresponding to the entire lower surface of the first substrate.

15. A method of fabricating an organic light emitting display device, comprising the steps of:
forming an aging voltage line on a support substrate;
disposing a first substrate including a plurality of sub-pixels on the support substrate;
forming a thin film transistor and an organic light emitting diode in each of the plurality of sub-pixels and on the first substrate;
connecting the aging voltage line to the thin film transistor by an aging voltage supply line; and
aging the thin film transistor by applying an aging voltage to the thin film transistor through the aging voltage line and the aging voltage supply line.

16. The method according to claim 15, wherein an aging pad is formed at an end of the aging voltage line.

17. The method according to claim 15, wherein the step of forming the thin film transistor includes:
forming a semiconductor layer over the first substrate and under a gate insulating layer;
forming a gate electrode on the gate insulating layer and under an interlayer insulating layer; and
forming a source electrode and a drain electrode on the interlayer insulating layer.

18. The method according to claim 17, wherein the step of connecting the aging voltage line to the thin film transistor by the aging voltage supply line includes:
forming a first aging voltage supply line in a first contact hole through the first substrate and the gate insulating layer and connected to the gate electrode; and
forming a second aging supply line in a second contact hole through the first substrate, the gate insulating layer and the interlayer insulating layer and connected to the drain electrode.

19. The method according to claim 17, wherein the step of connecting the aging voltage line to the thin film transistor by the aging voltage supply line includes:
forming a first aging voltage supply line in a first contact hole through the first substrate and the gate insulating layer and connected to the gate electrode;
forming a second aging supply line in a second contact hole through the first substrate and the gate insulating layer and connected to the metal pattern; and
forming a third aging supply line in a third contact hole through the interlayer insulating layer and connecting the metal pattern and the drain electrode.

20. The method according to claim 15, further comprising:
forming a sacrificial layer on the support substrate before the step of disposing the first substrate; and
separating the support substrate from the first substrate after the step of aging the thin film transistor.
